(19) United States
(12) Patent Application Publication
(10) Pub. No.: US 2011/0209987 A1
(43) Pub. Date: Sep. 1, 2011

(54) PRODUCTION OF AMORPHOUS AND CRYSTALLINE SILICON NANOCLUSTERS BY HYDROGEN ENHANCED REACTIVE MAGNETRON SPUTTERING WITHIN GAS AGGREGATION

(75) Inventors: Valery Garber, Yokneam Illit (IL); Alex Fayer, Herzliya (IL); Emanuel Baskin, Haifa (IL); Alexander Epstein, Haifa (IL)

(73) Assignee: D.C. SIRICA, LTD., Nesher (IL)

(21) Appl. No.: 13/128,643

(22) PCT Filed: Nov. 10, 2009
(86) PCT No.: PCT/IL2009/001055

§ 371 Date: May 11, 2011

Related U.S. Application Data
(60) Provisional application No. 61/113,599, filed on Nov. 12, 2008.

(51) Int. Cl. C23C 14/35; C23C 14/06; B82Y 40/00; B82B 3/00

(52) U.S. Cl. 204/192.15; 204/298.07; 204/192.12; 977/890

(57) ABSTRACT

A nanocluster source constituted of: a cooled aggregation chamber; a magnetron arranged to sputter a target, the magnetron in communication with the cooled aggregation chamber such that sputtered atoms of the target are received within the cooled aggregation chamber; a vacuum source in communication with the cooled aggregation chamber; a source of at least one noble aggregation gas in communication with the cooled aggregation chamber; and a source of hydrogen gas in communication with the cooled aggregation chamber. Advantageously, the hydrogen gas prevents oxidation of the target and silicon film covering a cooled inner surface of the aggregation chamber, and reduces the surface tension of the formed nanoclusters.

### BACKGROUND

The invention relates generally to the field of plasma nanocluster production, and more particularly to improved semiconductor, metal or metal oxide nanocluster production by the addition of hydrogen gas to the magnetron plasma.

Over the past decade, nanocluster research has been a topic of intense activity. The large amount of academic and industrial interest has arisen due to the novel electronic, optical, chemical and magnetic properties that nanoclusters possess. Current research in this field ranges from fundamental studies to practical film formation by both energetic and soft-landing clusters. In the next decade it is likely that nanoclusters will be used in nanodevices, optical data storage, magnetic data storage, and in the development of new materials.

Nanoclusters of silicon are of considerable interest due to their potential application in optoelectronics. At the nano-length scale, quantum confinement plays an important role in the electronic structure which has prompted studies in understanding the change in properties of materials as a function of size. A particular emphasis has been placed in understanding the changes in silicon, typically abbreviated as Si, which are a fundamental ingredient in most micro-electronic device.

The desirability of nanoclusters in general, and Si nanoclusters in particular, places a burden on developing methods for preparing them in the desired phase, size, shape, and contamination level. Preferably, a nanocluster source meeting industrial requirements should meet some, or all, of the following:
compatibility to large scale production;
compatibility for Si-based micro-fabrication technology;
parallel processing;
reasonable deposition rates;
control of nanocluster production, extraction and deposition;
control of both size and density of nanoclusters;
control of the shape of the deposited nanoclusters; and
stability, repeatability, high lateral resolution and uniformity.

Various methods of nanoparticles production are known, and considerable advantages are shown by vacuum nanocluster deposition systems initially designed by Professor H. Haberland, Freiburg University, Germany in the early 1990's. Such vacuum systems are designed specifically for the deposition of nanoclusters and are commercially available from a number of sources, including without limitation, Oxford Applied Research, and Mantis Deposition Ltd., both of Oxfordshires, U.K. These commercially available systems demonstrate a number of important advantages listed below:
Vacuum nanocluster source can be integrated with silicon-technology based microelectronic device fabrication—inherently compatible with silicon-based micro fabrication technologies;
Vacuum nanocluster source provides high yield of clusters formation with respect to input energy;
Nanocluster size may be controlled by adjusting any or all of the sputtering rate, the gas pressure and the residence time of the particles in the source volume;
Nanocluster size selection by mass spectrometric techniques and landing velocity control, particularly responsive to the fact that magnetron sputtering followed by gas aggregation generates nanoclusters of which up to 80% are negatively charged; and
Selection of a wide range of cluster sizes.

In principle, an important part of a nanocluster vacuum deposition system is a source of nanoclusters, preferably based on a magnetron discharge. The magnetron discharge provides atoms of a desired target material as a result of bombardment of a target by ions of a buffer gas with kinetic energy of several hundred eV, in a process known as sputtering. The atoms of the target material are channeled into a cooled aggregation zone, where a buffer noble gas, typically argon or a combination of argon and helium, provides conditions for super-saturation of the gas of sputtered material atoms moving towards an exit aperture. The term noble gas defines elements in group 18A (8A), which exhibit very low chemical activity. Often the term noble gas is used synonymously with inert gas, since the noble gasses form very few stable compounds.

The complex processes taking place in the super-saturated gas of sputtered material atoms, including without limitation homogenous nucleation, nucleus growth and evaporation, coalescence and coagulation leads to the aggregation of an ensemble of nanoclusters of the sputtered material having stationary size distribution. Aggregation of the nanoclusters, for a given magnetron configuration and power, is adjustable based on the type of noble gas or gasses utilized, the temperature and the temperature profile in the cooled aggregation zone and the distance between the magnetron and the exit aperture.

Unfortunately, the use of commercially available vacuum nanocluster deposition systems to produce Si nanoclusters shows limited success. This appears to be primarily a result of surface oxidation and charging of silicon in the cooled aggregation zone. The production of nanoclusters rapidly deteriorates over time, and can not be maintained for commercially viable period with fixed process parameters.

### SUMMARY

Accordingly, it is a principal object of the present invention to overcome at least some of the disadvantages of prior art nanocluster production, and particularly silicon nanocluster production by gas phase condensation. This is accomplished in certain embodiments by adding hydrogen as an additional aggregation gas to a nanocluster source for use in a vacuum environment. The use of hydrogen reduces the oxidation of both the silicon target and the silicon layer deposited on the walls of the reactor and further reduces the surface tension of produced silicon nanoclusters, thereby encouraging continued nucleation and growth of silicon nanoclusters.

In certain particular embodiments, hydrogen gas is introduced, constituting less than 1% of the flow rate of the total aggregation gasses. In certain other particular embodiments, hydrogen gas is introduced constituting more than 1% of the flow rate of the total aggregation gasses resulting in crystalline silicon nanoclusters. Preferably the hydrogen gas does not exceed 5% of the flow rate of the total aggregation gasses. In an exemplary embodiment the hydrogen gas is introduced as molecular hydrogen.

Additional features and advantages of the invention will become apparent from the following drawings and description.

### BRIEF DESCRIPTION OF THE DRAWINGS

For a better understanding of various embodiments of the invention and to show how the same may be carried into effect, reference will now be made, purely by way of example, to the accompanying drawings in which like numerals designate corresponding elements or sections throughout.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1 illustrates a high level schematic view of a cross section of a vacuum nanocluster source according to certain embodiments;

FIG. 2 illustrates a high level flow chart of a method operative with the vacuum nanocluster source of FIG. 1 to produce amorphous silicon nanoclusters according to certain embodiments;

FIG. 3 illustrates a high level flow chart of a method operative with the vacuum nanocluster source of FIG. 1 to produce crystalline silicon nanoclusters according to certain embodiments;

FIG. 4 illustrates a Raman spectrum of amorphous silicon nanoclusters deposited by the vacuum nanocluster source of FIG. 1 according to the method of FIG. 2; and

FIG. 5 illustrates a Raman spectrum of primarily crystalline silicon nanoclusters deposited by the vacuum nanocluster source of FIG. 1 according to the method of FIG. 3.

### DETAILED DESCRIPTION

Before explaining at least one embodiment in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

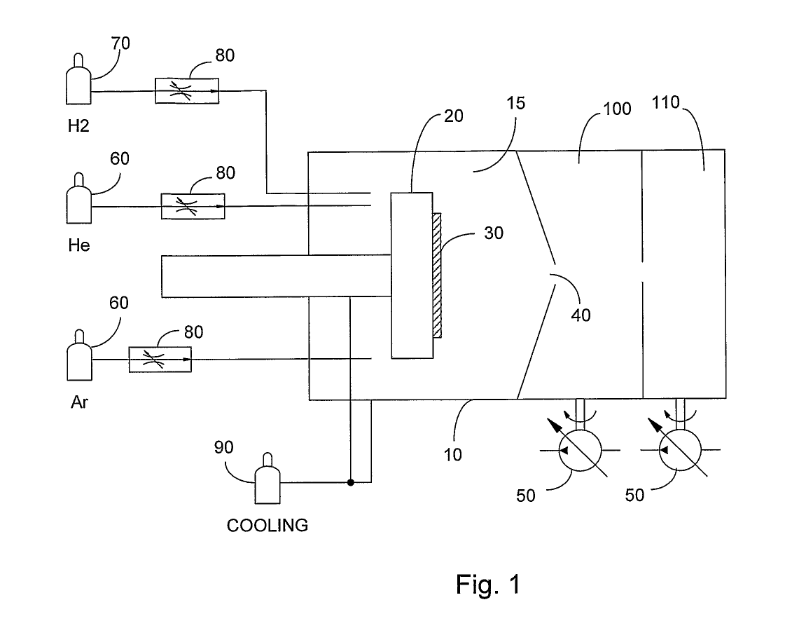

FIG. 1 illustrates a high level schematic view of a cross section of a vacuum nanocluster source according to certain embodiments comprising: a cooled aggregation chamber 10 exhibiting an aggregation zone 15; and having arranged thereon a magnetron 20 with a target 30; an exit aperture 40; a plurality of vacuum sources 50; a plurality of sources of noble aggregation gases 60; a source of hydrogen gas 70; a plurality of series flow controllers 80; a cooling source 90; an ion optics chamber 100; and a deposition chamber 110. In an exemplary embodiment target 30 is constituted of a silicon wafer. In an exemplary embodiment, source of hydrogen gas 70 provides molecular hydrogen gas.

Magnetron 20 is illustrated as being fixed at a predetermined location within cooled aggregation chamber 10, however this is not meant to be limiting in any way. In one embodiment the location of magnetron 20 is adjustable; particularly the distance between magnetron 20 and exit aperture 40 is adjustable.

Cooled aggregation chamber 10 is in communication with cooling source 90. Cooling source 90 is arranged to maintain aggregation zone 15 at a predetermined temperature appropriate for nanocluster aggregation. In one embodiment the temperature within aggregation zone 15 is maintained at about 300° K, and in one particular embodiment liquid nitrogen is provided by cooling source 90.

Each of the plurality of series flow controls 80 is connected to aggregation zone 15. Each one of plurality of sources of noble aggregation gas 60 is connected to a respective one of plurality of series flow controls 80. Source of hydrogen gas 70 is connected to a respective one of plurality of series flow controls 80. Thus, each of the sources of noble aggregation gasses 60 are arranged to deliver the constituent noble aggregation gasses via a respective series flow controller 80 to magnetron 20. In one embodiment, at least one of the noble aggregation gasses, preferably argon, is fed directly to a predetermined position in relation to magnetron 20, and cooling source 90 is further connected to magnetron 20. In one further embodiment, (not shown) the predetermined position is adjustable. An additional feed of the noble aggregation gasses (not shown) may be fed separately to another position in relation to magnetron 20 or to a position within cooled aggregation chamber 10. In another embodiment (not shown), sources of noble aggregation gases 60 are arranged to provide a mixing of the noble aggregation gases before they feed to magnetron 20.

Source of hydrogen gas 70 is arranged to deliver the constituent hydrogen gas via respective series flow control 80 directly to a predetermined position in relation to magnetron 20. In one further embodiment (not shown), the predetermined position is adjustable. In another embodiment (not shown), source of hydrogen gas 70 is arranged to deliver the constituent hydrogen gas via a respective series flow control 80 to one or more of magnetron 20 and cooled aggregation chamber 10. Series flow controls 80 are operative to control the flow of gas from the respective sources of noble aggregation gases 60 and source of hydrogen gas 70 to predetermined values.

Ion optics chamber 100 is in communication with exit aperture 40, and is further in communication with a respective vacuum source 50. Deposition chamber 110 is in communication with ion optics chamber 100, and is further in communication with a respective vacuum source 50.

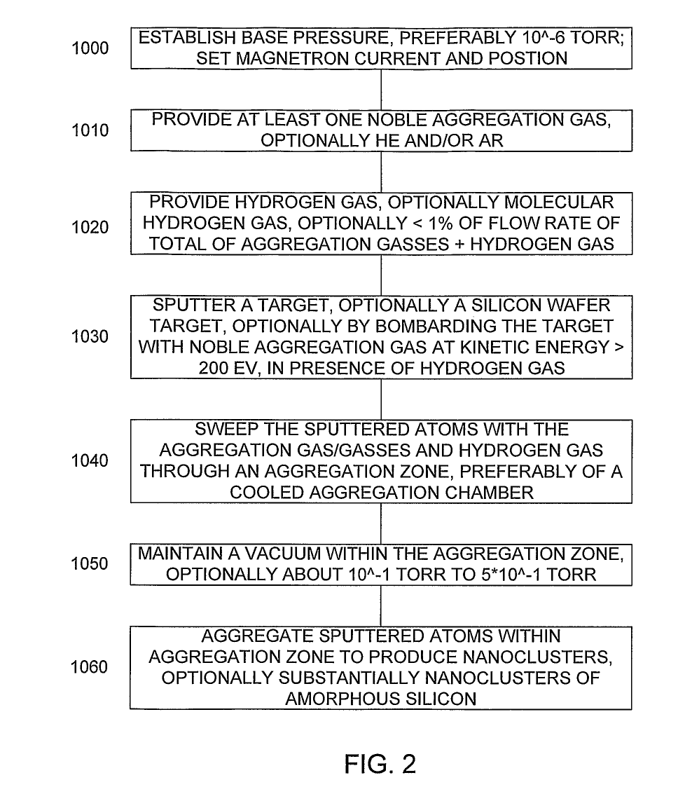

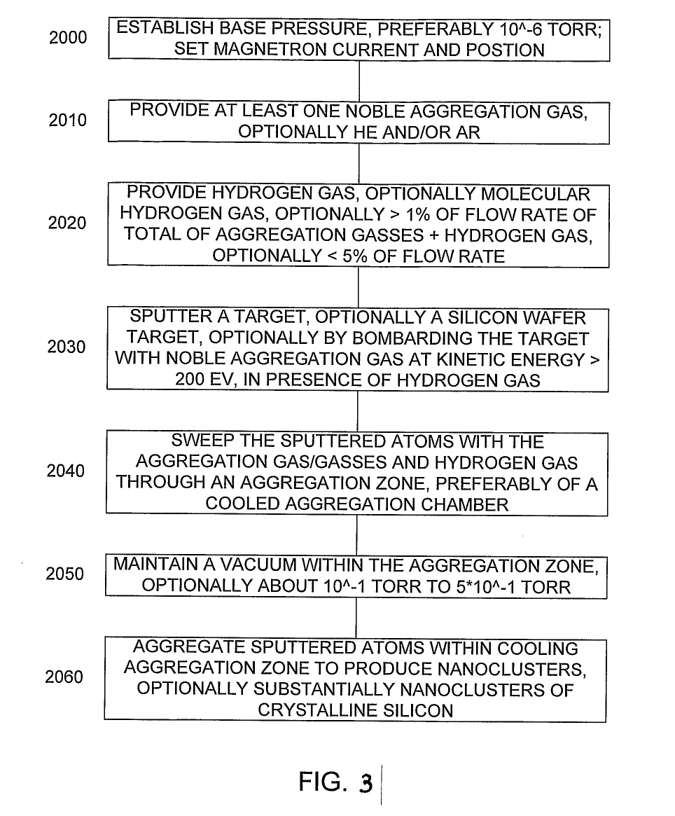

In operation, and as will be described further below in relation to FIGS. 2 and 3, the material to be deposited is used as target 30 of magnetron 20. Vacuum sources 50 are operative to maintain a base pressure in aggregation zone 15, preferably of about 10⁻⁶ Torr before the start of the sputtering process. Working pressure in the range of 10⁻¹ to 5×10⁻¹ Torr is provided as an inlet/outlet balance of the noble aggregation gases 60 and hydrogen gas 70 flowing through aggregation zone 15. After establishment of the desired initial working pressure, magnetron 20 is operative to bombard target 30 with gas ions accelerated to a kinetic energy greater than 200 eV. Atoms of target 30 are sputtered, responsive to the bombarding gas ions, and are swept by the provided noble aggregation gasses from source of noble aggregation gasses 60, and hydrogen gas from source of hydrogen gas 70, towards exit aperture 40. The sputtered atoms of target 30 form nanoclusters during the travel from target 30 towards exit aperture 40 as a result of their collisions, cooling and aggregation processes.

In one non-limiting example in which target 30 is constituted of a silicon wafer, silicon oxides of the prior art produced by oxidation of both surface of target 30 and the inner surface of cooled aggregation chamber 10, which is covered by a deposited film of sputtered silicon, is reduced by the addition of hydrogen from source of hydrogen gas 70. Additionally, it is believed that the addition of hydrogen functions to reduce the surface tension of produced silicon nanoclusters, thereby encouraging continued nucleation of silicon nanoclusters.

FIG. 2 illustrates a high level flow chart of a method operative with the vacuum nanocluster source of FIG. 1 to produce amorphous silicon nanoclusters according to certain embodiments. In stage 1000, a base pressure within the cooled aggregation chamber is established, preferably less than 1×10⁻⁶ Torr. A position for the magnetron is set, and the associated gas outlet positions are optionally set. A current for magnetron operation is determined and set.

In stage 1010, at least one noble aggregation gas is provided. Optionally, the at least one noble aggregation gas is argon. In certain embodiments both noble gasses argon and helium are provided.

In stage 1020, hydrogen gas is provided. Optionally, the provided hydrogen gas is molecular hydrogen gas. Optionally, the amount of hydrogen gas provided, and the amount of noble aggregation gas, or gasses, is controlled via the respective series flow control 80, such that the amount of hydrogen gas provided is less than 1% of the flow rate of the total gasses provided, i.e. the total of hydrogen gas provided and all noble aggregation gasses provided.

In stage 1030, a target is sputtered, such as target 30. Optionally, the target is a silicon wafer. Optionally, the target is sputtered by bombarding the target with provided ions of noble aggregation gasses at a kinetic energy greater than 200 eV, preferably in the presence of hydrogen gas. Advantageously, as described above, the use of hydrogen gas reduces oxidation of the silicon wafer target.

In stage 1040, the sputtered atoms from the target of stage 1030 are swept by the combination of noble aggregation gasses of stage 1010 and hydrogen gas of stage 1020, through aggregation zone 15, preferably of cooled aggregation chamber 10. In stage 1050 a working pressure is maintained within aggregation zone 15. Optionally, the working pressure is in the range of 1×10⁻¹ Torr to 5×10⁻¹ Torr.

In stage 1060, the sputtered atoms aggregate into nanoclusters within aggregation zone 15, as described in relation to stages 1040-1050, to produce nanoclusters. Optionally, responsive to the gas ratio of stage 1020, in the event of a silicon target, nanoclusters primarily of amorphous silicon are produced. In an exemplary embodiment, nanoclusters in excess of 95% amorphous silicon are continuously produced sufficient to deposit multiple layers on a substrate positioned in deposition chamber 110.

Maintaining the working conditions of stages 1000-1050, and in particular the working pressure of stage 1050, the noble aggregation gas flow and the hydrogen flow of stage 1020, and the position and current of the magnetron of stage 1000 preferably results in continuous production of nanoclusters, preferably of a desired sized distribution.

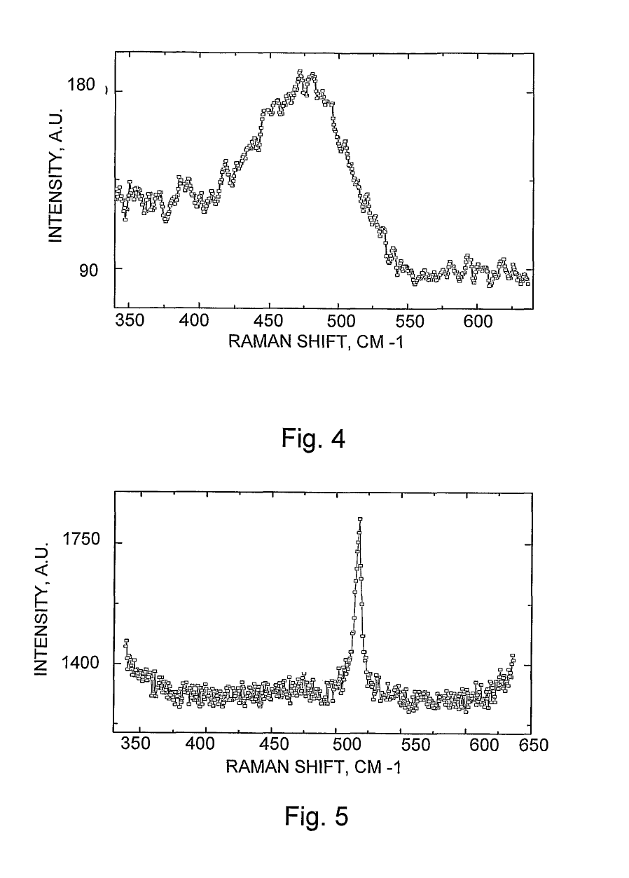

FIG. 4 illustrates a Raman spectrum of amorphous silicon nanoclusters deposited by the vacuum nanocluster source of FIG. 1 according to the method of FIG. 2, in which the x-axis represents the Raman shift of the probing light in cm⁻¹, and the y-axis represents scattered light signal intensity in arbitrary units. A broad distribution of intensities is exhibited up to about 525 cm⁻¹ with a broad peak centered at around 480 cm⁻¹, typical for amorphous silicon.

FIG. 3 illustrates a high level flow chart of a method operative with the vacuum nanocluster source of FIG. 1 to produce crystalline amorphous silicon nanoclusters according to certain embodiments. In stage 2000, a base pressure with the cooled aggregation chamber is established, preferably about 10⁻⁶ Torr. A position for the magnetron is set, and the associated gas outlet positions are optionally set. A current for magnetron operation is determined and set.

In stage 2010, at least one noble aggregation gas is provided. Optionally, the at least one noble aggregation gas is argon. In certain embodiments both noble gasses argon and helium are provided.

In stage 2020, hydrogen gas is provided. Optionally, the provided hydrogen gas is molecular hydrogen gas. Optionally, the amount of hydrogen gas provided, and the amount of noble aggregation gas, or gasses, is controlled via the respective series flow control 80, such that the amount of hydrogen gas provided is greater than 1% of the flow rate of the total gasses provided, i.e. the total of hydrogen gas provided and all noble aggregation gasses provided. Further optionally, the amount of hydrogen gas provided is greater than 1% and less than 5% of the flow rate of the total gasses provided.

In stage 2030, a target is sputtered, such as target 30. Optionally, the target is a silicon wafer. Optionally, the target is sputtered by bombarding the target with provided ions of noble aggregation gasses at a kinetic energy greater than 200 eV, preferably in the presence of said provided hydrogen gas. Advantageously, as described above, the use of hydrogen gas reduces oxidation of the silicon wafer target.

In stage 2040, the sputtered atoms from the target of stage 2030 are swept by the combination of noble aggregation gasses of stage 2010 and hydrogen gas of stage 2020, through aggregation zone 15, preferably of cooled aggregation chamber 10. In stage 2050 a working pressure is maintained within aggregation zone 15. Optionally, the working pressure is in the range of 1×10⁻¹ Torr to 5×10⁻¹ Ton.

In stage 2060, the sputtered atoms aggregate into nanoclusters within aggregation zone 15, as described in relation to stages 2040-2050, to produce nanoclusters. Optionally, responsive to the gas ratio of stage 2020, in the event of a silicon target, nanoclusters primarily of crystalline silicon are produced. In an exemplary embodiment, nanoclusters in excess of 95% crystalline silicon are continuously produced sufficient to deposit multiple layers on a substrate positioned in deposition chamber 110.

Maintaining the working conditions of stages 2000-2050, and in particular the working pressure of stage 2050, the noble aggregation gas flow and the hydrogen flow of stage 2020, and the position and current of the magnetron of stage 2000 preferably results in continuous production of nanoclusters, preferably of a desired sized distribution.

FIG. 5 illustrates a Raman spectrum of crystalline silicon nanoclusters deposited by the vacuum nanocluster source of FIG. 1 according to the method of FIG. 3, in which the x-axis represents the Raman shift of probing light in cm⁻¹, and the y-axis represents scattered light signal intensity in arbitrary units. A sharp peak intensity at about 520 cm⁻¹ is exhibited, indicative that primarily crystalline silicon nanoclusters have been deposited.

Thus certain of the present embodiments enable adding hydrogen as an additional aggregation gas to a nanocluster source for use in a high vacuum compatible environment. The use of hydrogen reduces the oxidation of silicon and reduces the surface tension of produced silicon nanoclusters, thereby encouraging continued nucleation and growth of silicon nanoclusters.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

Unless otherwise defined, all technical and scientific terms used herein have the same meanings as are commonly understood by one of ordinary skill in the art to which this invention belongs. Although methods similar or equivalent to those described herein can be used in the practice or testing of the present invention, suitable methods are described herein.

All publications, patent applications, patents, and other references mentioned herein are incorporated by reference in their entirety. In case of conflict, the patent specification, including definitions, will prevail. In addition, the materials, methods, and examples are illustrative only and not intended to be limiting.

It will be appreciated by persons skilled in the art that the present invention is not limited to what has been particularly shown and described hereinabove. Rather the scope of the present invention is defined by the appended claims and includes both combinations and sub-combinations of the various features described hereinabove as well as variations and modifications thereof, which would occur to persons skilled in the art upon reading the foregoing description.

1. A nanocluster source comprising:
a cooled aggregation chamber;
a magnetron arranged to sputter a target, said magnetron in communication with said cooled aggregation chamber such that sputtered atoms of said target are received within said cooled aggregation chamber;
a vacuum source in communication with said cooled aggregation chamber;
a source of at least one noble aggregation gas in communication with said cooled aggregation chamber; and
a source of hydrogen gas in communication with said cooled aggregation chamber.

2. A nanocluster source according to claim 1, wherein said magnetron is arranged within said cooled aggregation chamber.

3. A nanocluster source according to claim 1, wherein said source of hydrogen gas is in communication with said magnetron.

4. A nanocluster source according to claim 1, wherein said target is a silicon wafer.

5. A nanocluster source according to claim 1, wherein said vacuum source is arranged to produce a base pressure of about 1×10⁻⁶ Ton or less and a working pressure in the range of 1×10⁻¹ Ton to 5×10⁻¹ Torr within said cooled aggregation chamber.

6. A nanocluster source according to claim 1, wherein said source of hydrogen gas is a source of molecular hydrogen.

7. A nanocluster source according to claim 1, wherein said source of hydrogen gas is arranged to provide hydrogen gas of less than 1% of the flow rate of the total aggregation gasses provided by said source of at least one noble aggregation gas and said source of hydrogen gas.

8. A nanocluster source according to claim 7, wherein the nanocluster source produces substantially amorphous silicon nanoclusters

9. A nanocluster source according to claim 1, wherein said source of hydrogen gas is arranged to provide hydrogen gas of greater than 1% of the flow rate of the total aggregation gasses provided by said source of at least one noble aggregation gas and said source of hydrogen gas.

10. A nanocluster source according to claim 9, wherein the nanocluster source produces substantially crystalline silicon nanoclusters.

11. A nanocluster source according to claim 1, wherein said source of hydrogen gas is arranged to provide hydrogen gas of 1%-5% of the flow rate of the total aggregation gasses provided by said source of at least one noble aggregation gas and said source of hydrogen gas, and wherein the nanocluster source produces substantially crystalline silicon nanoclusters.

12. A method of producing nanoclusters, comprising:
sputtering a target;
providing at least one noble aggregation gas;
providing a hydrogen gas;
sweeping, by said provided at least aggregation gas and said hydrogen gas, the sputtered atoms of the target through an aggregation zone; and
maintaining a working pressure within the aggregation zone,
whereby said sputtered atoms aggregate to produce nanoclusters within the aggregation zone.

13. A method according to claim 12, wherein said sputtering comprises:
bombarding the target with ions of said provided at least one noble aggregation gas accelerated to a kinetic energy greater than 200 eV in the presence of said provided hydrogen gas.

14. A method according to claim 12, wherein the target is a silicon wafer.

15. A method according to claim 12, wherein said maintained working pressure is in the range of 1×10⁻¹ Torr to 5×10⁻¹ Torr.

16. A method according to claim 12, wherein said provided hydrogen gas is molecular hydrogen gas.

17. A method according to claim 12, wherein said provided hydrogen gas is less than 1% of the total flow rate of said provided at least one noble aggregation gas and said hydrogen gas.

18. A method according to claim 17, wherein said produced nanoclusters are substantially amorphous silicon nanoclusters.

19. A method according to claim 12, wherein said provided hydrogen gas is greater than 1% of the total flow rate of said provided at least one noble aggregation gas and said hydrogen gas.

20. A method according to claim 12, wherein said provided hydrogen gas is 1%-5% of the total flow rate of said provided at least one noble aggregation gas and said hydrogen gas.

21. (canceled)
